(19) United States
(12) Patent Application Publication
(10) Pub. No.: US 2026/0309752 A1
(43) Pub. Date: Oct. 8, 2026

(54) Device for Determining an Electric Current Through a Line in a Vehicle

(71) Applicant: Bayerische Motoren Werke Aktiengesellschaft, Muenchen (DE)

(72) Inventor: Hannes BOERNGEN, Muenchen (DE)

(21) Appl. No.: 19/640,779

(22) Filed: Apr. 7, 2026

(30) Foreign Application Priority Data
Apr. 8, 2025 (DE) 10 2025 113 674.2

(51) Int. Cl. G01R 15/20; B60L 3/00; G01R 19/00

(52) U.S. Cl. CPC G01R 15/202; B60L 3/0038; G01R 19/0092

(57) ABSTRACT

A device for determining an electric current through a line in a vehicle, including a magnetic core configured to run around the line in a ring-shaped manner, and which is at least partially interrupted along the ring-shaped profile by a first air gap and a second air gap. The device also has a magnetic field sensor located inside the first air gap and is configured to generate a sensor signal depending on a magnetic flux in the first air gap caused by the electric current. A gap width of the first air gap is smaller than a gap width of the second air gap. The device also has an evaluation unit to determine an actual value of the electric current depending on the sensor signal.

### CROSS-REFERENCE TO RELATED APPLICATION

This application claims priority under 35 U.S.C. §119 from German Patent Application No. DE 10 2025 113 674.2, filed Apr. 8, 2025, the entire disclosure of which is herein expressly incorporated by reference.

### BACKGROUND AND SUMMARY

The present disclosure relates to a device for determining an electric current through a line in a vehicle. Further aspects of the present disclosure relate to a vehicle which has such a device, and a method for determining an electric current through a line in a vehicle by such a device.

Devices are known from the prior art, in which an electric current through a line is determined. Contactless measuring devices which determine the electric current by a magnetic core may constitute a variant of these devices. In particular, such devices are also known for use in a vehicle.

In some embodiments, the line runs around the magnetic core in a ring-shaped manner. By way of example for this, mention may be made of the document DE 10 2021 111 412 A1, in which a current measuring system is presented for measuring, in particular indirectly measuring, a current flowing through an electrical current conductor. The current measuring system in this case has a magnetic core which has a feed-through opening and has a maximum cross-sectional area. In this case, the magnetic core is cut at a location to form an air gap. There, two cross-sectional faces of the magnetic core are exposed to delimit this air gap. At least one sensor is mounted at the magnetic core and arranged in the air gap in a positionally accurate manner, specifically for measuring a magnetic flux that is set for a current conductor guided through the feed-through opening with a current flowing through this current conductor.

A current measuring arrangement is known from WO 2010/106304 A1, which has a first and a second arm made from a magnetically permeable material, which arms are arranged such that they surround a cable which carries an electric current that is to be measured or detected. In this case, they come together at connecting points, wherein the arms and the connecting points form a magnetic circuit around the cable. A magnetic sensor, e.g. a Hall-effect sensor, is located in at least one of the connecting points, which is used for detecting or measuring the current. A cuff made from a magnetically permeable material is arranged and positioned such that it substantially encloses the connection housing the sensor when the arms are laid around the cable, in order to shield the first magnetic field sensor from stray magnetic fields. A gap may be present between the arms at the connection, in order to prevent the field generated by the current that is to be measured being conducted away from the sensor by the arms, and the cuff may have an opening directed toward the cable in order to prevent the sensor from being shielded from the field that is generated by the current.

It is fundamentally desirable to be able to determine the current as accurately or reliably as possible. This is possibly hindered, especially in the case of very high currents, if the magnetic core is operated in the range of its magnetic saturation and thus in the non-linear range.

An object of the present disclosure is to determine an electric current through a line, contactlessly in particular, with high accuracy and/or reliability.

This object is achieved according to the subject matter of the present disclosure. Advantageous embodiments are also the subject matter of the description and figures.

According to one aspect of the present disclosure, a device is presented for determining an electric current through a line, particularly an electrical line, in a vehicle. In this case, the device has a magnetic core which is configured to run around the line in a ring-shaped manner or to run around the line in a substantially or approximately ring-shaped manner. The magnetic core is in this case at least partially interrupted along the ring-shaped profile by a first air gap. The device has a magnetic field sensor which is located inside the first air gap and which is set up to generate a sensor signal depending on a magnet flux, also referred to as a magnetic flux, in the first air gap, which is caused by the electric current. The magnetic core is at least partially interrupted along the ring-shaped profile by a second air gap. In this case, a gap width of the first air gap is smaller than a gap width of the second air gap. The device has an evaluation unit which is set up to determine an actual value for the electric current through the line depending on the sensor signal.

The line can in this case in particular be a line for providing an electric power for a fully electric drive system or a hybrid drive system of the vehicle. In particular, the line can be a busbar, which has a rectangular cross section for example. The line is in particular designed in a single-core manner, that is to say has exactly one core or stranded wire, so that a possible return line is therefore located outside the ring-shaped profile for example. It is also possible that the line contains a plurality of cores, wherein a respective current direction through the plurality of cores is the same in particular.

The magnetic core in particular contains a material which has a high magnetic permeability, particularly high compared to a magnetic permeability of air. For example, the magnetic core has a ferromagnetic material or consists of the ferromagnetic material.

The ring-shaped profile can be circular and/or substantially circular and/or rectangular and/or substantially rectangular and/or oval and/or substantially oval. In other words, the magnetic core can be configured such that the ring-shaped profile runs in a loop-shaped manner or as a loop around the line. In particular, a shape of the ring-shaped profile can follow a cross-sectional geometry of the line, for example be adapted to a cross-sectional geometry of the line. In particular, the magnetic core can be configured, by the ring-shaped profile, such that the line is located at its center. For example, an inner diameter of the ring-shaped profile or the magnetic core is larger than an external diameter of a maximum cross section of the line. The magnetic core can therefore in particular be configured such that the line can be guided contactlessly through the ring-shaped profile. In other words, the magnetic core has, by the ring-shaped profile, a feed-through opening through which the line runs.

In particular, the device can have the line in at least one embodiment.

The first air gap can in other words also be referred to as a gap which interrupts the ring-shaped profile of the magnetic core with a material with a lower magnetic permeability. The first air gap can for example refer to an absence of the ferromagnetic material and can, but does not necessarily have to consist of air. The material with low magnetic permeability can for example be air and/or plastic and/or ceramic. In particular, the first air gap can also have a vacuum. In particular, the material with low magnetic permeability has a low electrical conductivity. Likewise, the second air gap can have the features of the first air gap to some extent or wholly.

The interruption of the magnetic core by the first and/or by the second air gap can in other words be understood as a change of the magnetic permeability along the ring-shaped profile owing to changed material characteristics. In particular, the magnetic core can have a first boundary surface at the first air gap, at which boundary surface the magnetic permeability changes abruptly from a high value to a low value inside the first air gap. Likewise, the magnetic core can have a second boundary surface at the first air gap with an opposite change.

In particular, the term gap width can also be referred to here and in the following as the length of a gap. The gap width of the first air gap can therefore refer to a length of the first air gap and the gap width of the second air gap can refer to a length of the second air gap.

A magnetic resistance can characterize a saturation behavior of the magnetic core, in other words the saturation magnetization of the magnetic core. The saturation behavior of the magnetic core may in particular depend on a cross-sectional area of the magnetic core and/or on a material of the magnetic core and/or on the gap width of the first air gap and/or on the gap width of the second air gap. In particular, the first gap and/or the second gap can lead to an increase of a value of a magnetic resistance of the magnetic core compared to a magnetic core which has the same external geometric dimensions and no air gap or only one of the two air gaps. In particular, here and in the following, the saturation behavior is considered relative to a magnetic field which is caused by the electric current flowing through the line.

A high value of the electric current through the line can lead to a high magnitude of the magnetic field, that is to say a high magnetic flux density. A linear increase of the electric current can, in the case of a saturated magnetic core for example, lead to a non-linear increase of the magnetic flux density. In particular, a linear increase of the electric current can, in the case of an unsaturated magnetic core for example, lead to a linear increase of the magnetic flux density. It may in particular be advantageous with respect to a resolution accuracy to use a range of the linear increase of the magnetic flux by the unsaturated magnetic core for determining the electric current through the line.

In particular, the second air gap does not adjoin the first air gap. For example, the second air gap is located opposite the first air gap on the ring-shaped profile.

In particular, the gap width of the first air gap is smaller by at least a factor of 2 or smaller by at least a factor of 5 or smaller by at least a factor of 10 than the gap width of the second air gap. The second air gap can, due to the larger gap width compared to the first air gap, also be referred to as a saturation gap.

The magnetic field sensor can in other words also be referred to as a magnetometer. The magnetic field sensor can contain a sensor apparatus for determining a magnetic field and/or a magnetic flux and/or a magnetic flux density. In particular, the magnetic field sensor can provide the sensor signal which for example corresponds to an electric voltage or is an electric voltage. An amplitude of the electric voltage can in this case be dependent for example on a value of the magnetic flux density or on a value of the magnetic flux of a magnetic field at a position of the magnetic field sensor. In particular, the magnetic field sensor can be located at a fixed position inside the first air gap.

In particular, the evaluation unit can be set up to evaluate the electric current that is determined and/or provide it to a further vehicle system, for example a control unit, ECU (electronic control unit). In particular, the evaluation unit can also be part of the ECU. The evaluation unit can have a data processing system.

The data processing system can for example be characterized as a device with processing circuits for processing data. The data processing system can for example carry out computing operations, in particular also comprising database accesses for reading and/or for storing data.

The data processing system can for example have a computer and/or a microcontroller and/or one or more integrated circuits. In this case, the data processing system can have at least one processor and/or at least one semiconductor chip. In addition, the data processing system can have at least one hardware interface and/or software interface which can for example be set up for receiving and/or for providing data.

The data processing system can in particular also have a storage unit for storing data, for example as a volatile data memory and/or as a non-volatile data memory and/or persistent data memory. In particular, the data processing system can have a semiconductor memory.

One advantage of the present disclosure is that the gap width of the first air gap and the gap width of the second air gap can be configured separately from one another. Thus, the gap width of the first air gap can be optimized for a measurement by the magnetic field sensor. Among other things, a very small gap width can be chosen for this, since a high field concentration and field homogeneity of the magnetic field caused by this can be advantageous for determination of the magnetic flux. Particularly for a highly accurate determination of a magnetic flux, a small air gap is advantageous. The magnetic field can be homogeneous and in particular uniform compared to the geometric dimension of the magnetic field sensor. In particular, a standard deviation of an absolute value of the magnetic field and/or the magnetic flux inside the first air gap can be smaller by a factor of 50 or by a factor of 100 than a standard deviation of the absolute value of the magnetic field and/or the magnetic flux inside the second air gap. The magnetic field sensor in the first air gap can therefore be considerably less sensitive to slight position changes and/or vibration than an alternative magnetic field sensor which would be arranged in the second air gap.

In addition, the gap width of the second air gap can be optimized to requirements with regard to the saturation behavior of the magnetic core. In particular, for adaptation to a measuring range which covers high current intensities, the gap width of the second air gap can be higher, in particular considerably higher, than the gap width of the first air gap. A second air gap can act as a saturation gap and correspondingly enable a range of application of the device at high or very high current intensities.

In particular, the requirements on an optimum gap width stemming from the placements of the sensor and from an adaptation of the saturation range may run counter to one another, so that, particularly in the case of a device which has only one air gap, a compromise must be found, which may jeopardize the attainment of both optimization goals. In particular, in the case of the device according to the present disclosure, independently of a possible reduction of the highly accurate determination of the magnetic flux by the magnetic field sensor, the saturation behavior of the magnetic core can only be adapted by a variation of the gap width of the second air gap.

According to at least one embodiment, the magnetic core is at least partially interrupted along the ring-shaped profile by a third air gap. The device has a further magnetic field sensor which is located inside the third air gap and which is set up to generate a further sensor signal depending on a further magnetic flux in the third air gap, which is caused by the electric current. In addition, a gap width of the third air gap is smaller than a gap width of the second air gap. In addition, the evaluation unit is set up to determine a further actual value for the electric current through the line depending on the further sensor signal.

In particular, the gap width of the third air gap can be the same size or a different size than the gap width of the first air gap. The further magnetic field sensor can in other words also be referred to as a further magnetometer. The further magnetic field sensor can contain a sensor apparatus for determining a magnetic field and/or a magnetic flux and/or a magnetic flux density in the third air gap. In particular, the further magnetic field sensor can have the same features or parts of the features of the magnetic field sensor.

By suitably choosing the gap width of the first air gap in conjunction with the gap width of the third air gap, it may be possible to cover different measuring ranges of the electric current using the device. Consequently, the magnetic field sensor can for example cover a first measuring range of the electric current with a high accuracy and the further magnetic field sensor can cover a second measuring range of the electric current with a high accuracy. In this case, the first measuring range and the second measuring range can overlap.

In particular, the third air gap is not located adjacent to the first air gap or to the second air gap. For example, the third air gap is located opposite the first air gap on the ring-shaped profile, at a distance from the second air gap.

The third air gap can in other words also be referred to as a further gap which interrupts the ring-shaped profile of the magnetic core with a material with a low magnetic permeability. The third air gap can for example refer to an absence of the ferromagnetic material. The material with low magnetic permeability can for example be air and/or plastic and/or ceramic. In particular, the material with low magnetic permeability has a low electrical conductivity. In particular, the third air gap can also have a vacuum.

The further actual value can be nominally identical or virtually identical to the actual value. For example, there may be redundancy reasons for the determination of the electric current by the further magnetic field sensor.

The evaluation unit can in particular be set up to compare the sensor signal with the further sensor signal. For example, the evaluation unit can be set up to determine and provide an average value of the actual and the further actual value. In particular, the evaluation unit may likewise only provide the actual value and/or the further actual value. Likewise, the device may contain a further evaluation unit in order to determine the further sensor signal.

One advantage of these embodiments is that, due to the further magnetic field sensor, the device is fail-safe with respect to a fault or failure of one of the magnetic field sensors. Likewise, an accuracy of the determination of the electric current can be increased owing to the determination by the further magnetic field sensor, for example by the suitable choice of the gap widths in relation to the measuring ranges. In particular, the gap width of the third air gap may be small compared to the gap width of the second air gap and correspondingly, the third air gap may have a homogeneous magnetic field. The saturation behavior of the magnetic core may remain substantially unchanged owing to the third air gap compared to the saturation behavior of the magnetic core without the third air gap and be adapted by the gap width of the second air gap.

According to at least one further embodiment, the device has a potting compound, particularly a potting compound consisting of a non-magnetic material.

According to at least one further embodiment, the magnetic field sensor is surrounded by the potting compound, particularly completely surrounded.

According to at least one further embodiment, the magnetic core is at least partially surrounded by the potting compound.

The potting compound may in this case be bitumen and/or resin and/or wax and/or plastic for example. Likewise, the line can for example be surrounded by the potting compound. Likewise, the further magnetic field sensor can for example be surrounded by the potting compound.

The potting compound can in particular protect the device from environmental influences, for example from moisture and/or from a gas and/or from a solid and/or from a vibration. Likewise, the potting compound can mechanically stabilize the device, particularly with respect to the interruption of the magnetic core by the first air gap and/or by the second air gap and/or by the third air gap. The potting compound can in particular have a material with low magnetic permeability.

One advantage of these embodiments is that owing to the potting compound, it is possible to ensure protection of the device, in particular it is possible to ensure protection from environmental influences. In addition, a mechanical stability of the device can be increased by the potting compound.

According to at least one further embodiment, the second air gap is completely filled with a non-magnetic material.

The non-magnetic material in this case has a low magnetic permeability, for example owing to an absence of a ferromagnetic material. In particular, the non-magnetic material can be air or plastic or ceramic or potting compound.

For example, the first air gap and/or the third air gap can be filled completely with the non-magnetic material.

According to at least one embodiment, the device has a ferromagnetic web which bridges, in particular completely bridges, the second air gap along the ring-shaped profile.

The ferromagnetic web can in particular contain the same material which the magnetic core contains or consist of the same material as the magnetic core. In particular, the second air gap is filled with the non-magnetic material along the ring-shaped profile except in a region which has the ferromagnetic web. The ferromagnetic web can in other words be referred to as a connection between a first part of the magnetic core and a second part of the magnetic core. In other words, the ferromagnetic web can be referred to as a magnetic short circuit of the second air gap.

One advantage of these embodiments is that a mechanical stability of the magnetic core can be increased owing to the ferromagnetic web. Likewise, the saturation behavior of the magnetic core can for example be influenced by a web width of the ferromagnetic web.

According to a further embodiment, a cross-sectional area of the ferromagnetic web is less than 20% or less than 5% of a cross-sectional area of the magnetic core at the second air gap.

In other words, the ferromagnetic web bridges the second air gap only to a small extent. In particular, a majority of the second air gap has the non-magnetic material.

The cross-sectional area of the ferromagnetic web compared to the cross-sectional area of the magnetic core can for example be configured such that the ferromagnetic web saturates even at low current intensities and consequently at higher and/or high current intensities only has a small or no influence on the saturation behavior of the magnetic core. The cross-sectional area of the ferromagnetic web can for example be as small as possible for this reason.

The insertion of the ferromagnetic web can in particular only influence the saturation behavior of the magnetic core slightly at higher and/or high current intensities. Furthermore, the ferromagnetic web can, due to its small cross-sectional area, have a small influence on an amplification behavior of the magnetic core at higher and/or high currents, that is to say at current intensities with a saturated ferromagnetic web. The amplification behavior in this case relates to an amplification of a detectable magnetic field in the first air gap of the magnetic core with respect to the electric current through the line around which the magnetic core runs.

One advantage of these embodiments is that the saturation behavior of the magnetic core can be configured toward high electric current intensities, as by a small cross-sectional area of the ferromagnetic web, only a small influence of the ferromagnetic web on the saturation behavior and/or the amplification behavior can be present at high current intensities.

According to at least one further embodiment, the device has a further ferromagnetic web which bridges the second air gap along the ring-shaped profile.

In particular, the features of the ferromagnetic web may apply in part or wholly for the further ferromagnetic web.

One advantage of these embodiments is that the mechanical stability can be increased further due to the further ferromagnetic web.

According to at least one further embodiment, the magnetic core has a laminated core and/or the magnetic core is realized as a laminated core and/or the magnetic core is realized in a laminated manner.

The laminated core can in this case in particular contain a material with high magnetic permeability, for example iron and/or an iron alloy and/or steel and/or a steel alloy. In particular, the laminated core can contain a ferromagnetic material.

In particular, the laminated core can contain at least one layer in the form of at least one electrical steel sheet which is cut out and/or blanked in a predetermined geometric shape. For example, the laminated core can be structured in a multilayered manner and correspondingly contain a multiplicity of such electrical steel sheets, which are stacked on top of one another in particular. In particular, the laminated core can be manufactured by a blanking process and/or by an adhesive bonding process based on the at least one layer of the electrical steel sheet.

One advantage of these embodiments is that the magnetic core can be manufactured as a laminated core fast and/or reproducibly and/or cost-effectively.

According to at least one embodiment, the laminated core has the ferromagnetic web and/or the further ferromagnetic web.

In other words, the ferromagnetic web and/or the further ferromagnetic web is part of the laminated core.

In particular, the at least one layer of the electrical steel sheet can likewise form the ferromagnetic web and/or the further ferromagnetic web. In particular, the laminated core can be designed in one piece and have the magnetic core and the ferromagnetic web and/or the further ferromagnetic web.

One advantage of this embodiment is that the laminated core can be produced cost-effectively and reproducibly by the blanking process or by the adhesive bonding process and the ferromagnetic web and/or the further ferromagnetic web can for example be created in the same work step.

According to at least one further embodiment, the magnetic field sensor has a Hall sensor or is a Hall sensor.

The Hall sensor can have a surface and be set up to provide an output voltage with a value that is dependent on a magnetic field running perpendicularly to the surface of the Hall sensor. The Hall sensor can for example detect the magnetic flux by the Hall effect.

One advantage of these embodiments is that the Hall sensor can be placed in the first air gap and further increases the accuracy of the determination of the electric current owing to its design and its measuring principle. In addition, a cost advantage may result due to the use of the Hall sensor.

According to a further aspect of the present disclosure, a vehicle having a line and a device according to the present disclosure is presented, wherein the magnetic core of the device runs around the line in a ring-shaped manner.

According to at least one embodiment, the vehicle has a fully electric drive system or a hybrid drive system having an electrical subsystem, wherein the device is a constituent of the electric drive system or the hybrid drive system.

A further aspect of the present disclosure relates to a method for determining an electric current through a line in a vehicle by the device according to the present disclosure. In this case, the magnetic core of the device runs around the line in a ring-shaped manner. In addition, a sensor signal is generated depending on a magnetic flux in the first air gap, which is caused by the electric current. In addition, an actual value for the electric current through the line is determined depending on the sensor signal.

Further features of the present disclosure emerge from the figures and the description of the figures. The features and feature combinations mentioned previously in the description and also the features and feature combinations mentioned in the following in the description of the figures and/or shown solely in the figures can be used not only in the respectively specified combination, but also in other combinations or in isolation.

Embodiments of the present disclosure are explained in more detail in the following with reference to schematic drawings.

Other objects, advantages and novel features of the present disclosure will become apparent from the following detailed description of one or more preferred embodiments when considered in conjunction with the accompanying drawings.

### BRIEF DESCRIPTION OF THE DRAWINGS

FIG. 1 shows a schematic illustration of a motor vehicle as embodiment for a vehicle according to various aspects of the present disclosure having an embodiment of a device for determining an electric current through a line in a vehicle according to the present disclosure; and

FIG. 2 shows a schematic illustration of an embodiment of a device according to the present disclosure; and

FIG. 3 shows a perspective illustration of an embodiment of a device according to the present disclosure; and

FIG. 4 shows a schematic illustration of a further embodiment of a device according to the present disclosure; and

FIG. 5 shows a perspective illustration of a further embodiment of a device according to the present disclosure; and

FIG. 6 shows a schematic illustration of a further embodiment of a device according to the present disclosure; and

FIG. 7 shows a perspective illustration of a further embodiment of a device according to the present disclosure; and

FIG. 8 shows a schematic illustration of a further embodiment of a device according to the present disclosure; and

FIG. 9 shows a schematic illustration of a further embodiment of a device according to the present disclosure; and

FIG. 10 shows a perspective illustration of a further embodiment of a device according to the present disclosure; and

FIG. 11 shows a graphical representation of simulation data with regard to at least one embodiment of a device according to the present disclosure; and

FIG. 12 shows a graphical representation of simulation data with regard to at least one embodiment of a device according to the present disclosure; and

FIG. 13 shows a graphical representation of simulation data with regard to at least one embodiment of a device according to the present disclosure; and

FIG. 14 shows a graphical representation of simulation data with regard to at least one embodiment of a device according to the present disclosure.

### DETAILED DESCRIPTION OF THE DRAWINGS

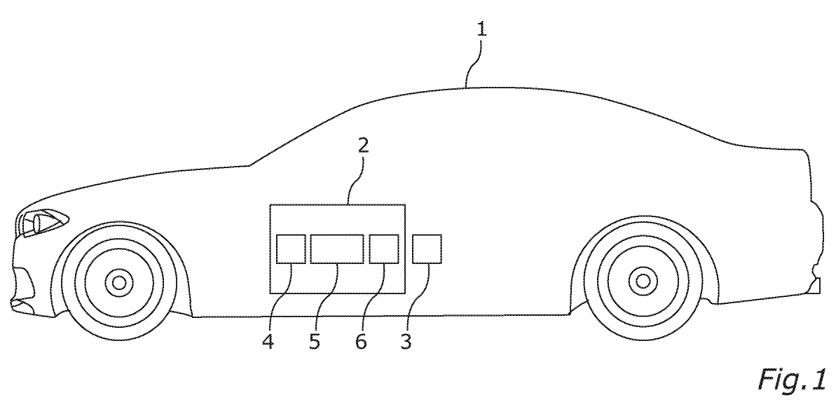

FIG. 1 shows a vehicle 1 in a schematic illustration. The vehicle 1 is a motor vehicle here. It may for example be a passenger car or a truck or a bus.

The vehicle 1 has a device 2 according to the present disclosure for determining an electric current through a line 3. The device has at least a magnetic core 4, a magnetic field sensor 5, and an evaluation unit 6.

The line 3 can for example be configured to provide an electrical power to a drive system of the vehicle 1. In particular, the drive system can drive the vehicle 1 fully electrically or in a hybrid manner, that is to say partially electrically.

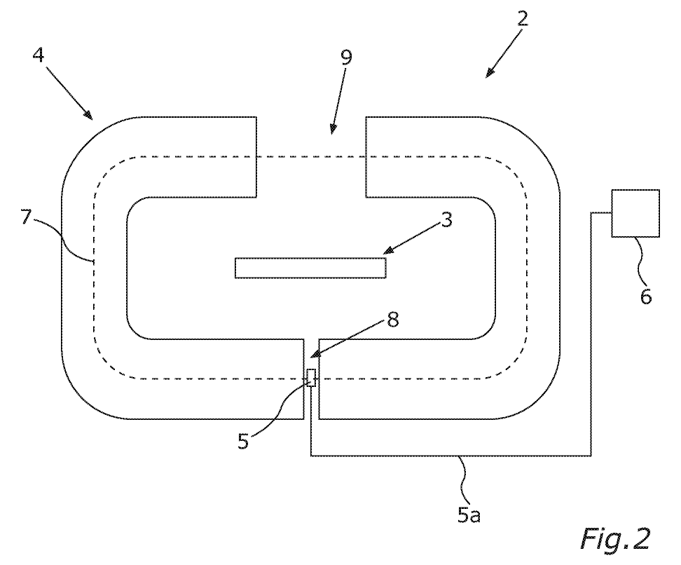

The magnetic core 4 of at least one embodiment of the device 2 is shown in FIG. 2 in a schematic sectional illustration. In this case, the magnetic core 4 runs around the line 3 in a ring-shaped manner. In other words, the line 3 runs through a feed-through opening in the magnetic core 4 orthogonally to the drawing plane. The line 3 is illustrated in the illustration as busbar. In one embodiment, the device 2 may contain the line 3.

The magnetic core 4 is at least partially interrupted along the ring-shaped profile 7 by a first air gap 8, and in the embodiment shown is interrupted completely. In other words, the first air gap 8 in particular refers to a complete interruption of the magnetic core 4 along the ring-shaped profile 7, particularly by a material with a low magnetic permeability, particularly with a relative permeability with a value in the region of one. The material can for example be air and/or plastic and/or ceramic and/or potting compound. The first air gap 8 can run uniformly in the direction of the line 3.

The magnetic field sensor 5 is located inside the first air gap 8 and is set up to generate a sensor signal 5a depending on a magnetic flux in the first air gap 8, which is caused by the electric current. In particular, the sensor signal 5a can be made available for the evaluation unit 6. The sensor signal 5a can for example be an electric voltage, the amplitude of which depends on a value of the magnetic flux in the first air gap 8.

The magnetic field sensor 5 is located particularly in a fixed manner at a center or close to a center of the first air gap 8. For example, the magnetic field sensor 5 inside the first air gap 8 and/or the magnetic core 4 can be potted or overmolded.

The magnetic core 4 is additionally at least partially interrupted along the ring-shaped profile 7 by a second air gap 9, and in the embodiment shown is interrupted completely. All or a portion of the features of the first air gap 8 may apply for the second air gap 9. In particular, there is no magnetic field sensor 5 in the second air gap 9.

A gap width of the first air gap 8 is smaller than a gap width of the second air gap 9. For example, the gap width of the first air gap 8 is smaller by at least a factor of 2 or smaller by at least a factor of 5 or smaller by at least a factor of 10 than the gap width of the second air gap 9.

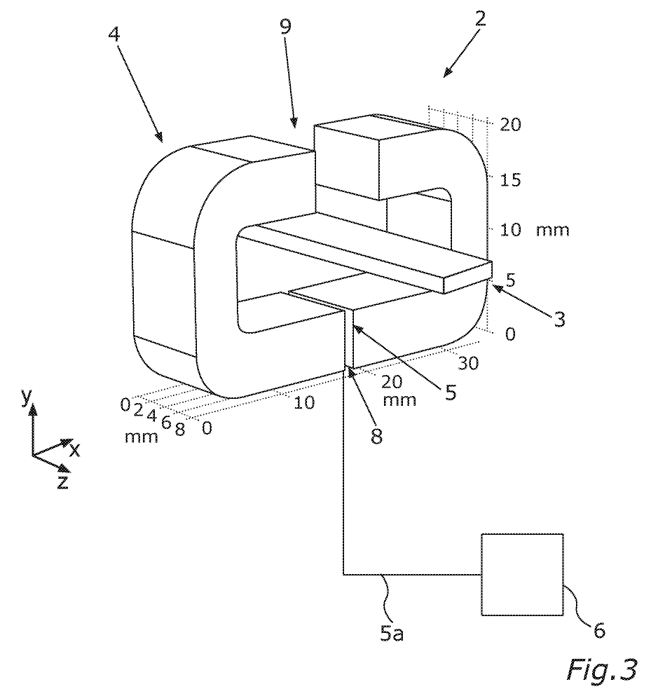

In FIG. 3, the device 2 from FIG. 2 is illustrated in a perspective view. In this case, an embodiment is chosen, using which it is possible to determine a current range of for example up to 1000 A through the line 3. To this end, the magnetic core 4 has a width in the x direction of for example 35 mm, a height in the y direction of for example 20 mm and a thickness in the z direction of for example 8 mm. The first air gap 8 here has a width of for example 1 mm and the second air gap 9 has a width of for example 6 mm. The dimensions specified here and in the following constitute approximate values or orientation guides and may be subject to tolerances.

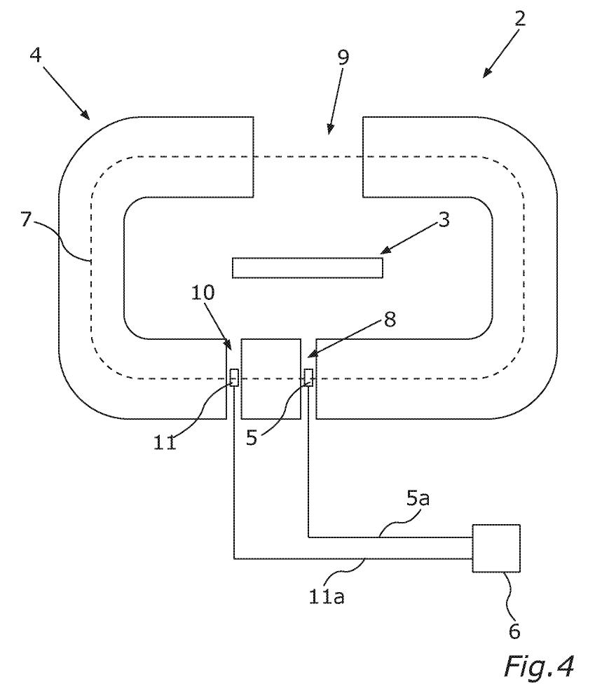

FIG. 4 shows a further embodiment of the device 2. The embodiment may in particular contain all or a portion of the features of the embodiment from FIG. 2 and/or FIG. 3.

In particular, the device 2 in FIG. 4 has a third air gap 10, which at least partially interrupts the ring-shaped profile 7 of the magnetic core 4, and in particular interrupts it completely. The third air gap 10 is located neither adjacent to the first air gap 8 nor adjacent to the second air gap 9.

Inside the third air gap 10, there is a further magnetic field sensor 11, which is set up to generate a further sensor signal 11a depending on the magnetic flux in the third air gap 10, which is caused by the electric current through the line 3, and to make the further sensor signal available to the evaluation unit 6 for example. The further sensor signal 11a can for example be a further electric voltage, the amplitude of which depends on a measured value of the magnetic flux in the third air gap 10.

A gap width of the third air gap 10 in the embodiment shown is equal to the gap width of the first air gap 8. As a consequence, the sensor signal 5a and the further sensor signal 11a may lie in a similar value range. Likewise, by varying the gap width of the first air gap 8 in conjunction with the gap width of the third air gap 10 in a targeted manner, it is possible to bring about a different value range of the sensor signal 5a and the further sensor signal 11a.

In particular, the sensor signal 5a may be dependent on a position of the magnetic field sensor 5 inside the first air gap 8 and the further sensor signal 11a may be dependent on a position of the further magnetic field sensor 11 inside the third air gap 10.

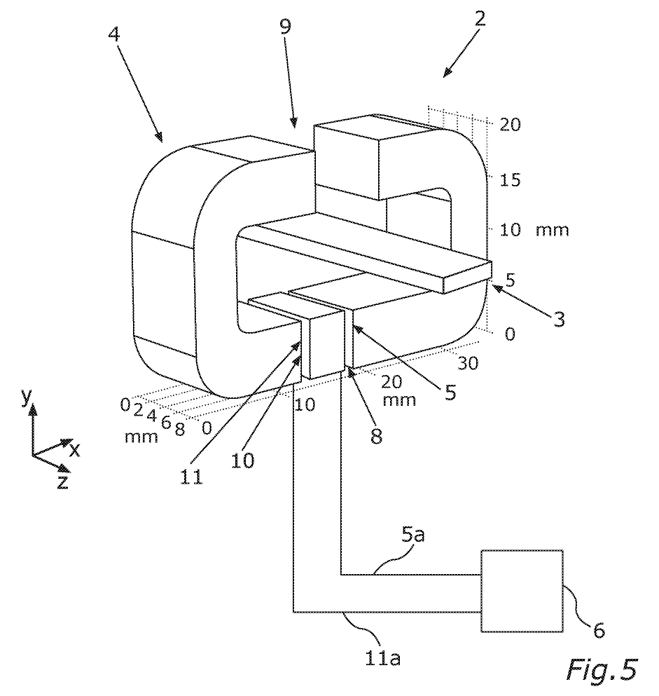

In FIG. 5, the device 2 from FIG. 4 is illustrated in a perspective view. In this case, an embodiment is chosen, using which it is possible to determine a current range of for example up to 1000 A through the line 3. To this end, the magnetic core 4 has a width in the x direction of 35 mm, a height in the y direction of 20 mm and a thickness in the z direction of 8 mm. The first air gap 8 here has a width of 1 mm and the second air gap 9 has a width of 6 mm. The third air gap 10 has a width of 1 mm.

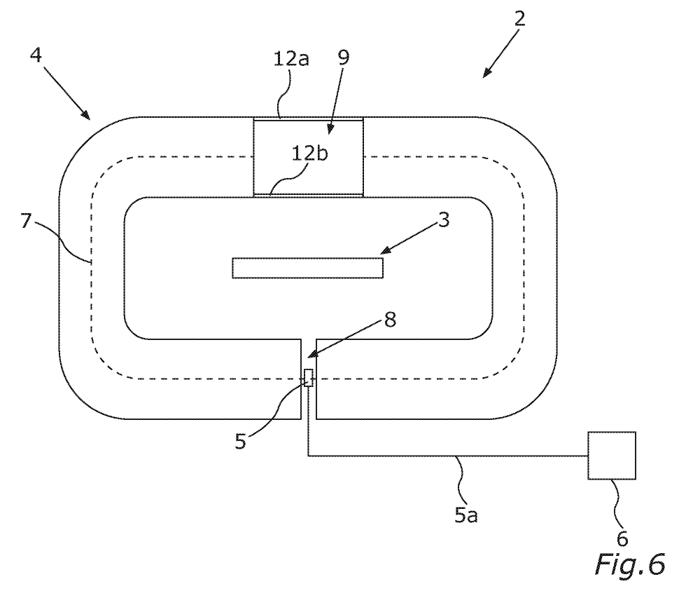

FIG. 6 shows a further embodiment of the device 2. The embodiment may in particular contain all or a portion of the features of the embodiment from FIG. 2, FIG. 3, FIG. 4 and/or FIG. 5.

In particular, the device 2 in FIG. 6 has a ferromagnetic web 12a. The ferromagnetic web 12a bridges the second air gap 9 completely, in other words the magnetic core 4 is partially interrupted at the second air gap 9 by the ferromagnetic web 12a, and in particular not completely interrupted. The ferromagnetic web in particular has a material with high magnetic permeability. For example, the magnetic core 4 may have the same material that the ferromagnetic web 12a has. Embodiments are possible in which the magnetic core 4 and the ferromagnetic web 12a form a unit, in other words are designed in one piece.

A width of the ferromagnetic web 12a in a radial direction with respect to the center point of the magnetic core 4 can in particular be small or very small compared to the gap width of the second air gap 9 and/or compared to a wall thickness of the magnetic core 4 in the radial direction. In other words, a volume of the second air gap 9 can be filled mostly with the material with low magnetic permeability and only to a small extent with the material with high magnetic permeability owing to the ferromagnetic web 12a.

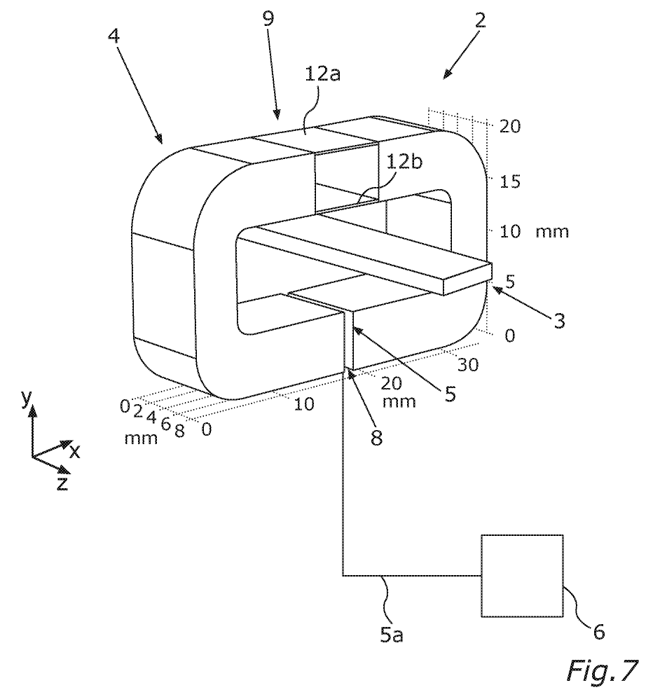

Furthermore, the device 2 can have a further ferromagnetic web 12b. The features of the ferromagnetic web 12a may also apply wholly or in part for the further ferromagnetic web 12b. In the embodiment in FIG. 6 and FIG. 7, the ferromagnetic web 12a is located in particular on an outer radius of the magnetic core 4 and the further ferromagnetic web 12b is located in particular on an inner radius of the magnetic core 4.

In FIG. 7, the device 2 from FIG. 6 is illustrated in a perspective view. In this case, an embodiment is chosen, using which it is possible to determine a current range of for example up to 1000 A through the line 3. To this end, the magnetic core 4 has a width in the x direction of 35 mm, a height in the y direction of 20 mm and a thickness in the z direction of 8 mm. The first air gap 8 here has a width of 1 mm and the second air gap 9 has a width of 6 mm. The ferromagnetic web 12a here has a width of 0.5 mm perpendicular to the ring-shaped profile 7. The further ferromagnetic web 12bhere has a width of 0.5 mm perpendicular to the ring-shaped profile 7.

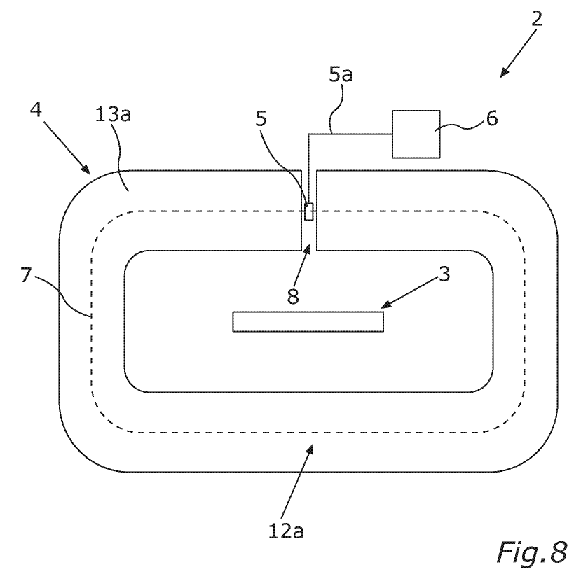

FIGS. 8, 9, and 10 show further examples of embodiments of the device 2. The embodiments may in particular contain all or a portion of the features of the embodiment from FIGS. 2, 3, 4, and/or 5.

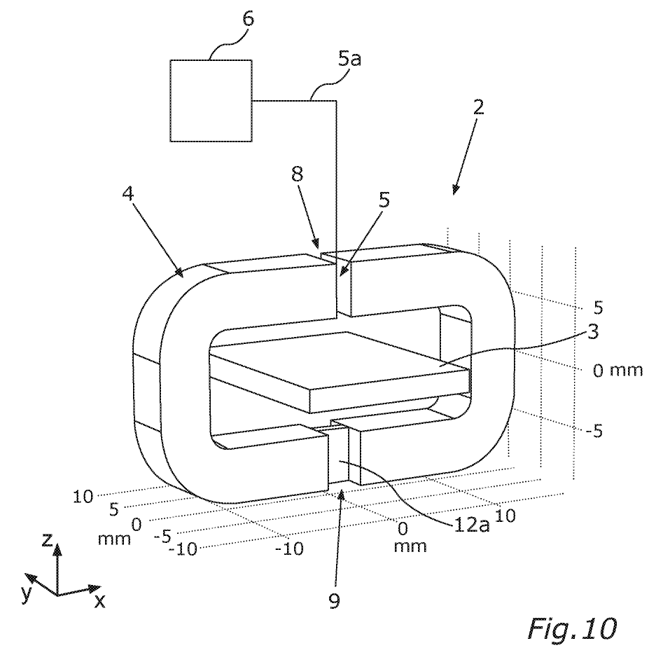

In particular, the device 2 has the ferromagnetic web 12a which, compared to the embodiment in FIGS. 6 and 7, is rotated by 90° about an axis of rotation which runs from one end of the second air gap 9 to the opposite end of the second air gap 9 (see in particular FIG. 10 compared to FIG. 7). The ferromagnetic web 12a bridges the second air gap 9 completely, in other words the magnetic core 4 is not completely interrupted at the second air gap 9 by the ferromagnetic web 12a.

A width of the ferromagnetic web 12a in the direction of a course of the line 3 can in particular be small or very small compared to the gap width of the second air gap 9 and/or compared to a wall thickness of the magnetic core 4 in the direction of a course of the line 3. In other words, the volume of the second air gap 9 can be filled mostly with the material with low magnetic permeability and only to a small extent with the material with high magnetic permeability owing to the ferromagnetic web 12a.

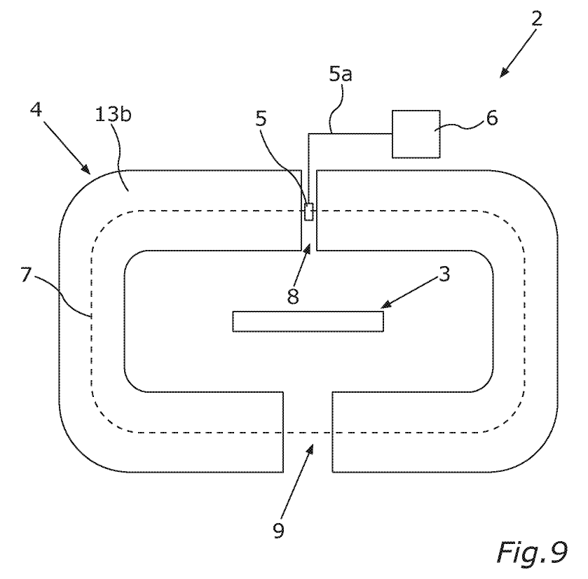

The magnetic core 4 can in particular be realized in a laminated manner or realized as a laminated core. In other words, the magnetic core 4 can have at least one layer 13a, 13b in the form of an electrical steel sheet, particularly a blanked electrical steel sheet. In particular, a first layer 13a of the at least one layer 13a, 13b can have an electrical steel sheet which differs from a second layer 13b of the at least one layer 13a, 13b. For example, the ferromagnetic web 12a can be part of the first layer 13a (see FIG. 8) and the second layer 13b can have the second air gap 9 at an identical position (see FIG. 9). By connecting at least one electrical steel sheet, the geometry of which corresponds to a geometry of the first layer 13a, to at least one further electrical steel sheet, the geometry of which corresponds to a geometry of the second layer 13b, a laminated core can be created, as is shown in FIG. 10.

In FIG. 10, the device 2 from FIGS. 8 and 9 is illustrated in a perspective view. The ferromagnetic web 12a here has a width of 0.3 mm in the direction of a course of the line 3. The width of the ferromagnetic web 12a can in particular correspond to a thickness of a single electrical steel sheet, that is to say for example of the second layer 13b, or correspond to a multiple of a thickness of the electrical steel sheet.

According to various embodiments of the device 2, the magnetic core 4 can be realized to be saturated in some areas, for example by a gradation of the second air gap 9 or a narrowing of the magnetic core 4 or a combination of a plurality of materials with corresponding characteristics. As a result, a high sensitivity can be achieved at low electric currents through the line 3. At medium electric currents through the line 3, a saturation of a saturable area and the magnetic core 4 shows a transient characteristic. At high electric currents through the line 3, the saturable area may be strongly saturated, as a result of which the saturable area has a good approximation of a magnetic behavior of air and thus extends an effective second air gap. This reduces a magnetic field strength at high currents and thus prevents overloading of the magnetic field sensor 5.

By dimensioning the saturable area, it is possible to configure a sensitivity in the range of low currents and configure non-overloading of the magnetic field sensor 5 in the range of high currents without adjustment.

A saturation behavior of electrical steel sheet is often shown in the form of curves which plot a magnetic polarization (𝐽) over a magnetic field strength (𝐻). Alternatively, a magnetic flux density can be shown (𝐵) over the magnetic field strength. Both illustrations are to be considered as equivalent in particular.

In the range of small magnetic field strengths, an electrical steel sheet may exhibit a steep rise of a resultant magnetic flux density, this corresponds to a high relative magnetic permeability (𝜇_{𝑟}). From a magnetic field density of e.g. approx. 100 𝐴/𝑚, this rise may transition to a distinctly flatter rise; a material saturates in this transition region. At high field strengths, the material can be considered as virtually completely saturated; the slope of the curve then corresponds to vacuum permeability (or the permeability of air), that is to say an absolute permeability of 𝜇₀.

The saturation behavior is considered disadvantageous in a plurality of the technical applications of magnetically conductive materials, that is to say materials with a relative permeability greater than one, for example electrical steel sheet or ferrite material. A reduction of the magnetic conductivity can for example lead in the case of electric machines (electric motors, generators) to a reduction of coupling between rotor and stator and as a result to impairment of an efficiency. A further effect is an increase of a power that is required for magnetization of the electric machine, that is to say an increase of the magnetization requirement. A similar effect can be observed in the case of inductors or transformers. Here, a current that grows markedly due to saturation of a magnetic component can lead to increased losses in a surrounding circuit. The increased losses can in particular lead to the destruction of the magnetic component or the surrounding circuit. It is possible to make use of this generally disadvantageous effect of saturation of magnetically conductive materials in the case of arrangements for the metrological detection of electric currents.

In at least one embodiment of the device 2, the ferromagnetic web 12a, which can also be referred to as a constriction of the magnetic core 4 in the second air gap 9, is introduced in the second air gap 9, (see FIGS. 7 and 10). Obviously, the constriction may also be present at other or a plurality of positions of the magnetic core 4.

The constriction can be manufactured from the same material as the magnetic core 4. It is also possible that the ferromagnetic web 12a has a different material with different desired characteristics. One possibility is to make it possible to configure a saturation of a subarea differently from another area.

The ferromagnetic web 12a, which in the following can also be referred to as a saturation web, can be manufactured from the same material as the laminated core. The following sizes can be considered as possible design parameters of the device 2:
the gap width of the first air gap 8, which can also be referred to as the length or gap width of a sensor air gap, and/or
the gap width of the second air gap 9, which can also be referred to as the length or gap width of a saturation gap, and/or
the width of the saturation web.

The width of the saturation web can be considered in a first approximation as a design parameter for a configuration for a value of the electric current which leads to a saturation of the saturation web. The gap width of the second air gap 9, which can also be referred to as the length of the saturation web, and the gap width of the sensor air gap can be considered as design parameters for a configuration of a field strength of the magnetic field at the magnetic field sensor 5 in the case of a maximum current and in the case of approximately complete saturation of the saturation web.

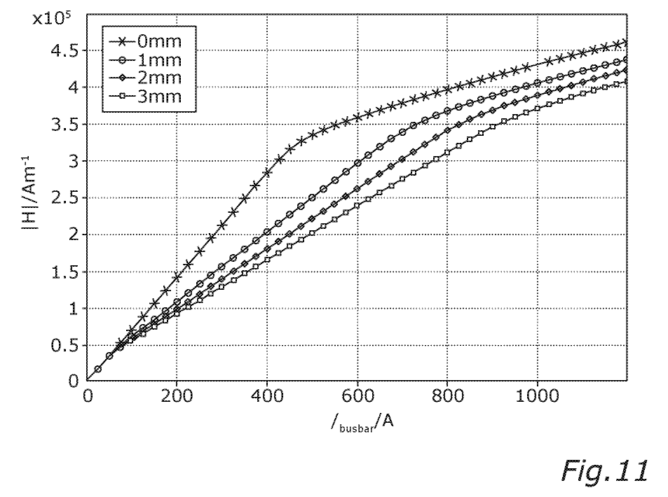

Various options exist for clarifying an effect of the length of the saturation web. For example, the length of the sensor air gap can be kept constant and the influence of the introduction of saturation webs of different lengths or gap widths of the second air gap 9 can be investigated. Simulation data for an embodiment of the device are illustrated in FIG. 11. Here, in the case of saturation webs of different lengths, different effective total air gap lengths result after saturation of the saturation web.

In FIGS. 11, 12, 13, and 14, simulation data for different embodiments of the device 2 are illustrated graphically. In this case, values of the electric current (𝐼_{𝑏𝑢𝑠𝑏𝑎𝑟}/A) through the line 3 are respectively shown on an x axis and a respectively resulting value of the magnetic field strength (|H|/Am⁻¹) brought about by the respective value of the electric current is shown on a y axis.

FIG. 11 (variable total air gap length as sum of sensor air gap length (1.4 mm) and saturation web length as parameter) for example shows that in the range of small currents through the line 3, at currents smaller than approx. 50 A, the magnetic field strengths, which can be metrologically detected by the magnetic field sensor 5 in the sensor air gap, are approximately commensurate in all four illustrated cases. Only the relatively short length of the sensor air gap is relevant for the behavior in this range. According to the simulation data, the sensitivity of the device cannot be limited at small currents by introducing the saturation web. As a result of this, it is possible to achieve a signal-to-noise ratio that can be used well even in the case of small currents that are to be detected.

From currents that are greater than 100 A for example, the saturation web may be approximately completely saturated, as a result of which no transition region may be discernible in FIG. 11 for example. If it is assumed for the magnetic field sensor 5 that this magnetic field sensor can detect magnetic fields up to 300 A/mm⁻¹, for example can detect them without overloading, the following correlations result: In the case without a saturation web (a curve labeled with stars in FIG. 11), that is to say without a second air gap 9, the sensor signal 5a of the magnetic field sensor 5 can for example only be used for detecting the electric current at currents less than or equal to 425 A. If a saturation web of 1 mm length (a curve labeled with circles in FIG. 11), 2 mm length (a curve labeled with diamonds in FIG. 11) or 3 mm length (a curve labeled with squares in FIG. 11) is introduced, a measuring range of the device 2 can for example be extended to 600 A, 700 A or 775 A.

A secondary effect of a longer saturation web and/or a longer saturation gap is a shift of the electric current to higher values at which the magnetic core 4 saturates entirely. One advantage of the device 2 may be that in the case of the same sensitivity at low currents, a greater maximum current can still reliably be metrologically detected. This can be seen in FIG. 11 in that up to approximately 50 A, all four chosen designs are approximately equal, so no degradation of the signal is to be expected at low currents.

An effect of the saturable area following saturation of the saturation web is considered in the following if an effective total air gap length is kept constant. Here also, the effective total air gap length is composed approximately additively from the share of the sensor air gap and the share of the saturable area. Expressed differently, when configuring the effective total air gap length of the air gap that is effectively present at high currents can be chosen as a fixed value which is composed approximately from the length of the sensor air gap and the length of the (saturated) saturation web and/or the saturation gap.

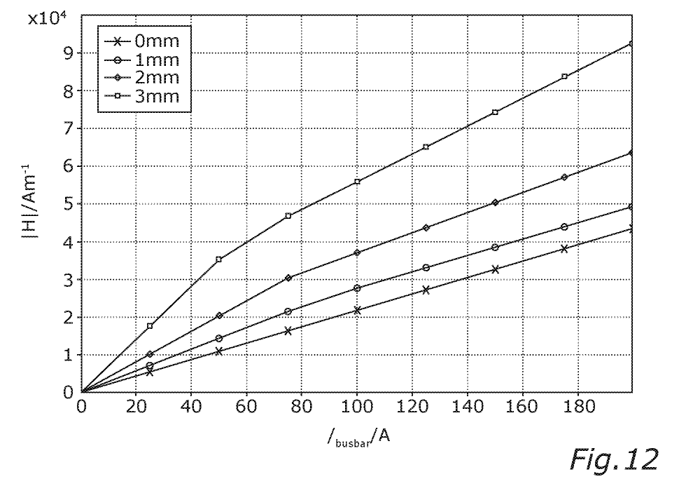

This alternative approach for visualizing an effect of the length of the saturation web is shown in the graphical representation of simulation data in FIG. 12 (constant total air gap length (4.4 mm) as a sum of sensor air gap length and saturation web length as parameters). In FIG. 12, simulation data without a saturation web, that is to say without a second air gap 9, are labeled with stars, simulation data with a length of the saturation web of 1 mm are labeled with circles, simulation data with a length of the saturation web of 2 mm are labeled with diamonds, and simulation data with a length of the saturation web of 3 mm are labeled with squares.

For this, a detail cutout was chosen in the case of low currents, that is to say in the range in which the saturation web transitions from unsaturated to saturated. From this, it can clearly be seen that by changing the distribution of the length of the sensor air gap to the length of the saturation web, it is possible to set an increase of the sensitivity at low currents.

In the case of a specification that the effective total air gap length is not to be changed, it turns out to be disadvantageous that when the measuring range is delimited by the magnetic field sensor 5, the measuring range is limited to high currents.

This characteristic can be avoided however if the length of the sensor air gap and the length of the saturation web are chosen in a suitable manner. Expressed differently, it is possible in the event of a corresponding choice of the length of the sensor air gap and suitable choice of the length of the saturation web to achieve a combination of higher sensitivity at low currents and extension of the measuring range at high currents.

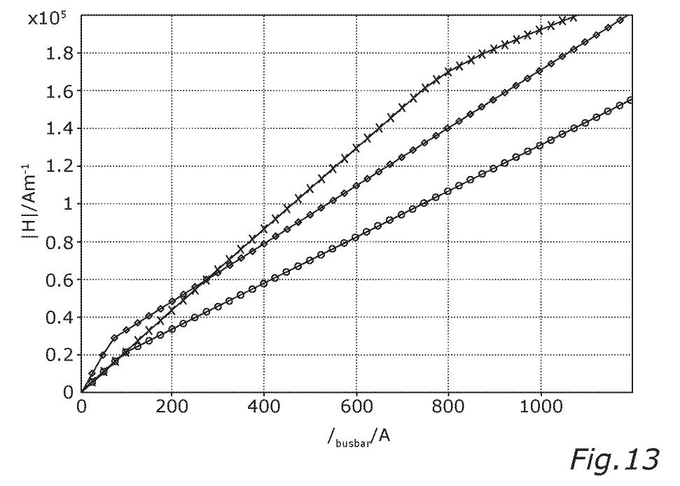

Simulation data with parameters chosen in such a manner are illustrated in FIG. 13 (optimized individual air gap lengths with increased sensitivity at low currents and extended measuring range at high currents). In FIG. 13, simulation data with a length of the sensor air gap of 4.4 mm without saturation web, that is to say without a second air gap 9, are labeled with stars, simulation data with a length of the sensor air gap of 4.4 mm and a length of the saturation web of 5 mm are labeled with circles, and simulation data with a length of the sensor air gap of 2.5 mm and a length of the saturation web of 12 mm are labeled with diamonds.

Following the argumentation with delimitation by the magnetic field sensor 5, a magnetic field sensor 5 which overloads from 140 A mm⁻¹ for example is assumed in this case. In an arrangement according to the prior art, a current up to a maximum of approx. 640 A can for example be measured, i.e. in accordance with the curve which is keyed with stars in FIG. 13. In an embodiment of the device 2 with the same length of the sensor air gap and a length of the saturation web of 5 mm, it is possible to measure currents up to 1075 A with the same sensitivity in the range of small currents (curve keyed with circles in FIG. 13).

If the length of the sensor air gap is chosen to be 2.5 mm and the length of the saturation web is chosen to be 12 mm, it is possible that the sensitivity is increased in the range of small currents and the measuring range can be extended to 800 A at the same time (curve keyed with diamonds in FIG. 13).

With correspondingly adjusted values, it is possible to configure the device 2 such that it is possible to achieve increased sensitivity at low currents at the same time as extension of the measuring range at maximum currents. By way of an example for this, mention may be made of the devices 2 in FIG. 13 for which the simulation data are keyed graphically in the curves with circles and with diamonds.

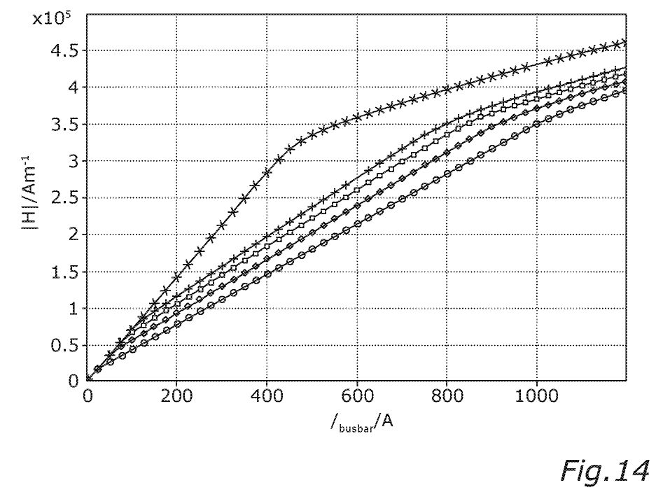

An influence of the width of the saturation web is presented in the following as a further characteristic to be investigated. FIG. 14 (variable saturation web width as parameter and saturation gap length constant 4.4 mm) illustrates simulation data which show the behavior of various arrangements. In FIG. 14, simulation data with a width of the saturation web of 0.3 mm are labeled with circles, simulation data with a width of the saturation web of 0.6 mm are labeled with diamonds, simulation data with a width of the saturation web of 0.9 mm are labeled with squares, simulation data with a width of the saturation web of 1.2 mm are labeled with crosses, and simulation data with a width of the saturation web which corresponds to a width of the magnetic core 4, that is to say a device which has no saturation gap, that is to say without a second air gap 9, are labeled with stars.

A range of measurable currents, that is to say for example a range with a linear shape, can be extended to larger currents by changing the width of the saturation web, as can be seen in FIG. 14. By varying the width of the saturation web, it is possible to set the electric current which leads to the saturation of the saturation web. The larger the width of the saturation web chosen, the higher the value of the electric current that leads to saturation of the web.

The magnetic core 4 can be realized in a laminated manner. The laminated core of the magnetic core 4 can be manufactured from a multiplicity of, for example blanked, electrical steel sheets. FIG. 8 is presented as an example for the shape of such an electrical steel sheet. An electrical steel sheet of this type has a specifiable thickness (for example 0.3 mm), wherein eddy currents in the laminated core can be suppressed better by using thinner metal sheets. The multiplicity of the electrical steel sheets can be assembled to form a laminated core by welding to one another, adhesive bonding to one another or the like. The cutout in the upper limb of the magnetic core 4 represents the first air gap 8 for introducing the magnetic field sensor 5.

In the device 2, a saturation web can for example be created in a simple manner in that one portion of the electrical steel sheets of this type according to FIG. 8 and a remaining portion of the electrical steel sheets according to FIG. 9 are joined to one another. Here, a cutout is placed at a different location which in combination with an electrical steel sheet according to FIG. 8 may constitute a constriction in the laminated core.

This lamination also makes it possible to combine electrical steel sheets with different material characteristics. For example, the electrical steel sheets that should saturate at a chosen current, thus which therefore represent the saturation web, can be chosen according to corresponding material characteristics. In this case, the saturation web, that is to say the electrical steel sheet according to FIG. 8 can be arranged both centrally in the laminated core and outside of a center. Also, arrangements with a continuous or discontinuous change of electrical steel sheets according to FIGS. 8 and 9 are conceivable.

In one embodiment of the device 2, a value with a magnetic flux density of approx. 500 mVs m⁻² (500 mT) can be brought about in the saturation web by a value of the electric current of 25 A. The saturable area cannot be saturated at the saturation web at this current. A value of the magnetic field that results in the sensor air gap may for example correspond to 17 A mm⁻¹.

At a value of the electric current of 250 A, it is possible to bring about a value of the magnetic flux density in the saturation web of 1.8 Vs m⁻² (1.8 T). Unlike in the case of 25 A, the saturable range may already be completely saturated for 250 A. A value of the magnetic field in the sensor air gap may be approx. 100 A mm⁻¹ in this case.

Saturation of the entire saturation web may approximately have a magnetic characteristic of a vacuum. The length of the saturation web can therefore contribute to the total air gap length and at high currents, particularly from the saturation of the saturation web, influence the field strength in the sensor air gap.

If a magnetic reluctance model is used, it may for example be taken into consideration that a sum of the length of the sensor air gap and the length of the saturation web, that is to say the length of the saturation gap, may for example be shorter than the effective total air gap length.

The foregoing disclosure has been set forth merely to illustrate the present disclosure and is not intended to be limiting. Since modifications of the disclosed embodiments incorporating the spirit and substance of the present disclosure may occur to persons skilled in the art, the present disclosure should be construed to include everything within the scope of the appended claims and equivalents thereof.

### LIST OF REFERENCE SIGNS

1 Vehicle
2 Device
3 Line
4 Magnetic core
5 Magnetic field sensor
5a Sensor signal
6 Evaluation unit
7 Ring-shaped profile
8 First air gap
9 Second air gap
10 Third air gap
11 Further magnetic field sensor
11a Further sensor signal
12a Ferromagnetic web
12b Further ferromagnetic web
13a First layer
13b Second layer

What is claimed is:

1. A device for determining an electric current through a line in a vehicle, the device comprising:
a magnetic core configured to run around the line in a ring-shaped profile, wherein the magnetic core is at least partially interrupted along the ring-shaped profile by a first air gap;
a magnetic field sensor that is located inside the first air gap and which is configured to generate a sensor signal depending on a magnetic flux in the first air gap that is caused by the electric current,
wherein the magnetic core is at least partially interrupted along the ring-shaped profile by a second air gap,
wherein a gap width of the first air gap is smaller than a gap width of the second air gap; and
an evaluation unit configured to determine an actual value for the electric current through the line depending on the sensor signal.

2. The device according to claim 1,
wherein the magnetic core is at least partially interrupted along the ring-shaped profile by a third air gap,
wherein the device comprises:
a further magnetic field sensor that is located inside the third air gap and which is configured to generate a further sensor signal depending on a further magnetic flux in the third air gap that is caused by the electric current,
wherein a gap width of the third air gap is smaller than a gap width of the second air gap, and
wherein the evaluation unit is configured to determine a further actual value for the electric current through the line depending on the further sensor signal.

3. The device according to claim 1, comprising:
a potting compound, wherein the potting compound at least one of surrounds the magnetic field sensor and/or at least partially surrounds the magnetic core.

4. The device according to claim 1,
wherein the second air gap is completely filled with a non-magnetic material.

5. The device according to claim 1, comprising:
a ferromagnetic web that bridges the second air gap along the ring-shaped profile.

6. The device according to claim 5,
wherein a cross-sectional area of the ferromagnetic web is less than 20% of a cross-sectional area of the magnetic core at the second air gap, or less than 5% of a cross-sectional area of the magnetic core at the second air gap.

7. The device according to claim 1,
wherein the magnetic core has a laminated core and/or is realized as a laminated core and/or is realized in a laminated manner.

8. The device according to claim 7,
wherein the laminated core comprises a ferromagnetic web that bridges the second air gap along the ring-shaped profile.

9. The device according to claim 1,
wherein the magnetic field sensor comprises a Hall sensor.

10. A vehicle comprising:
a line; and
the device according to claim 1, wherein the magnetic core of the device runs around the line in a ring-shaped manner.

11. The vehicle according to claim 10, comprising:
a fully electric drive system or a hybrid drive system comprising an electrical subsystem,
wherein the device is a constituent of the electric drive system or the hybrid drive system.

12. A method for determining an electric current through a line in a vehicle by a device,
wherein the device comprises:
a magnetic core configured to run around the line in a ring-shaped profile, wherein the magnetic core is at least partially interrupted along the ring-shaped profile by a first air gap;
a magnetic field sensor that is located inside the first air gap and which is configured to generate a sensor signal depending on a magnetic flux in the first air gap that is caused by the electric current,
wherein the magnetic core is at least partially interrupted along the ring-shaped profile by a second air gap,
wherein a gap width of the first air gap is smaller than a gap width of the second air gap; and
an evaluation unit configured to determine an actual value for the electric current through the line depending on the sensor signal,
wherein the magnetic core of the device runs around the line in a ring-shaped manner,
wherein the method comprises:
generating a sensor signal depending on a magnetic flux in the first air gap caused by the electric current; and
determining an actual value for the electric current through the line depending on the sensor signal.
